(19) United States
(12) Patent Application Publication
(10) Pub. No.: US 2025/0179683 A1
(43) Pub. Date: Jun. 5, 2025

(54) THERMAL CHIMNEY FOR CRYSTAL GROWTH

(71) Applicant: John Outwater, Bedford, MA (US)

(72) Inventor: John Outwater, Bedford, MA (US)

(21) Appl. No.: 18/969,576

(22) Filed: Dec. 5, 2024

Related U.S. Application Data
(60) Provisional application No. 63/606,273, filed on Dec. 5, 2023.

(51) Int. Cl. C30B 15/34; C30B 15/32; C30B 29/20

(52) U.S. Cl. CPC C30B 15/34; C30B 15/32; C30B 29/20

(57) ABSTRACT

The presently disclosed technology teaches a thermal chimney, comprising: an insulation providing a space for crystal growth; an enclosure housing the insulation; wherein the insulation further includes: a bottom level lined with tungsten plates, hanging from a first bar; a second level lined with graphite plates, hanging from a second bar; a third level lined with soft graphite felt; a seed shaft and a seed holder housed in the insulation; two layers of lids placed at the top of the insulation and the enclosure; two layers of seals respectively placed in a middle of the two layers of lids, secured to the seed shaft.

### TECHNICAL FIELD

The present disclosure generally relates to material science and chemical engineering.

### BACKGROUND

For the growth of clear sapphire crystals at a high speed, a steep and linear vertical thermal gradient is needed above the die. The bottom of the growing crystal may be at or close to its melting point, 2,050° C. The top of the crystal may be as much as 1,000° C. lower. The thermal expansion differential at these two temperatures is very substantial. A linear temperature gradient is optimal for crystal growth, preventing the crystal from cracking. On the other hand, if the gradient deviates too much from being linear, the crystal may crack during the cooling-down or even growth process. A non-linear thermal gradient also introduces internal stress into the crystal itself and weakens it.

There is a tradeoff between maintaining a steep thermal gradient and minimizing heat loss. The gradient is formed by cooling down the top end of a chimney. This tradeoff can be minimized by minimizing the cross-sectional area of the chimney at an opening above the die.

A serious problem engineers may face during the growth of sapphire caused by the EFG (Edge-defined, Film-fed Growth) is called “ferns”, which refers to voluminous vapor-phase deposits of various oxides and carbides. The ferns may build up on the inside of the chimney, surrounding the growing crystal. The ferns may block heat flow, gas flow, visual access to the inside of the chimney, and the growth of the sapphire crystal itself. If they fall on the die, they may react with it, causing severe damage to the often-expensive die.

Therefore, it could be helpful to have an environment or vessel for the effective growth of clear sapphire crystals.

### SUMMARY

The detailed description set forth below in connection with the appended drawings is intended as a description of presently preferred embodiments of the invention and does not represent the only forms in which the present disclosure may be constructed and/or utilized. The description sets forth the functions and the sequence of steps for constructing and operating the invention in connection with the illustrated embodiments.

The present disclosure teaches a thermal chimney for a growing crystal, wherein the thermal chimney may provide a steep and linear thermal gradient in a vertical direction. The thermal chimney may also minimize heat losses and prevent fern growth. It is also desirable to minimize the area of the opening above the die to minimize heat loss. A higher level of heat loss requires a higher power input, which in turn makes overheating and degradation of the liquid sapphire in the crucible more likely. The presently disclosed thermal chimney may minimize the heat loss while providing the required thermal gradient.

In some embodiments, the thermal chimney may include rectangular blocks of rigid graphite felt. These blocks may be separated by gaskets of soft graphite felt, to control gas flow. The entire thermal chimney assembly may be housed within an aluminum enclosure, which protects the thermal chimney from reacting with the ambient air. The enclosure may alternatively be made of other materials that are corrosion-resistant and have sufficient structural strength.

In some embodiments, a lowest level of rigid graphite felt may be lined with tungsten plates. These plates, each of which may be about an inch wide, may hang from a graphite bar. The bottoms of the plates may be approximately level with the bottom of the growing crystal. Tungsten may protect the felt insulation from sapphire and tungsten vapors, as the temperature at this level is approximately 1,950° C.

The next level may be lined with graphite plates, also hanging from a graphite bar. These plates may be larger, at about 4″ wide in some embodiments. Graphite may be necessary to protect the felt insulation, as the temperature is ˜1,850° C. at this level.

The next level may be lined with three layers of soft graphite felt. The temperature at this level may be or approximately be the precipitation temperature of the carbide and oxide vapors, at which they condense into solid particles, which form ferns. The soft graphite felt may adsorb these impurities, inhibiting the formation of ferns. This configuration may provide a substantial reduction and, in many cases, elimination of the formation of ferns, which solves a common problem in the art.

The top level of rigid felt insulation may not be lined at all. In many embodiments, it may be capped with a transparent quartz cover, which may seal to both the felt chimney (on its bottom) and the aluminum enclosure (on its edges). It may have a hole in the middle to allow passage of the seed shaft and seed holder (attached to the end of the seed shaft). The gap between the top of the cover and the seed shaft is sealed by a thin floating quartz disk, which serves as a one-way seal, preventing air from entering the chimney. Argon may flow up the chimney during operation, which may cause the disk to float.

Similarly, in some embodiments, the aluminum chimney may be capped with a clear quartz window, with an opening to allow the seed shaft and seed holder to pass through. Similarly, the gap between the seed shaft and the surface of the window may be covered by a floating graphite disk, which may serve as a one-way seal to prevent air from entering the chimney. Again, the disk may float because of the argon flowing up the chimney.

In some embodiments, two levels of floating seals may be used to prevent air ingress, as thermal circulation within the chimney may create negative pressure for brief periods. A single floating seal could potentially allow air to be sucked in.

The seed and seed shaft have been described in U.S. Pat. Nos. 11,713,519 and 11,713,520, which are hereby incorporated herein by reference.

A quartz lid or lids may allow visual access to the top of the die during the process of spreading (lateral growth of the crystal). With visual access, an operator may control and adjust the process accordingly. This allows the spread to proceed as fast as possible while avoiding the risk of polycrystallinity, which could easily develop if the spread proceeds in an uncontrolled manner. The quartz lids also allow visual access to the top of the crystal and across the entire height of the chimney during the entire growth run (a single cycle or session in which a crystal is grown under controlled conditions).

As shown in the figures, the chimney contemplated herein has hanging plate insulation 1540 (also referred to herein as “insulation” or the “bottom level of insulation”), and tungsten hanging plate 1423 (“tungsten plates”), with hanging foil insulation 1584 (“insulation” or the “second level of insulation”) and H.G.I. liner 1742 (“graphite plates”) adjacent to it. Next to these is the fern foyer 1591 with three layers of graphite felt (the third level of insulation). Adjacent to this is the upper felt chimney (the top level of insulation). A chimney plate 1492 (“enclosure” or “aluminum enclosure”) extends past these elements. Within the upper felt chimney area is the seed holder 1470 and seed for A-plane growth 1438. A quartz felt chimney lid 1622 operates as a lid, with a lower shaft seal 1455 and upper shaft seal 1429 providing sealing of seed shaft 1446. The lid has a quartz window 1456 as well as an aluminum chimney lid. Individual views of these components included herein provide detail views of the components.

While several variations of the present disclosure have been illustrated by way of example in preferred or particular embodiments, it is apparent that further embodiments could be developed within the spirit and scope of the present disclosure, or the inventive concept thereof. However, it is to be expressly understood that such modifications and adaptations are within the spirit and scope of the present disclosure, and are inclusive of, but not limited to the following appended claims as set forth.

### BRIEF DESCRIPTION OF THE DRAWINGS

The present disclosure is further illustrated by way of exemplary embodiments, which are described in detail through the accompanying drawings. These embodiments are not limiting, and in these embodiments, the same numbering indicates the same structure, wherein:

FIG. 1A is an isometric view diagram showing the presently disclosed thermal chimney, according to some embodiments of the present disclosure;

FIG. 1B is a front view thereof;

FIG. 1C is a side view thereof;

FIG. 1D is a cross-sectional view thereof, in the front view direction;

FIG. 1E is a cross-sectional view thereof, in the side view direction;

FIG. 2 is a cross-sectional view showing a lower part of the presently disclosed thermal chimney, in the side view direction, according to some embodiments of the present disclosure;

FIG. 3 is a cross-sectional view showing an upper part of the presently disclosed thermal chimney, in the side view direction, according to some embodiments of the present disclosure;

FIG. 4 is a cross-sectional view showing an upper part of the presently disclosed thermal chimney, in the front view direction, according to some embodiments of the present disclosure.

### DETAILED DESCRIPTION

In order to more clearly illustrate the technical solutions of the embodiments of the present disclosure, the accompanying drawings for the description of the embodiments are described below. Obviously, the accompanying drawings in the following description are only some examples or embodiments of the present disclosure, and it is possible for a person of ordinary skill in the art to apply the present disclosure to other similar scenarios in accordance with these accompanying drawings without creative labor. Unless obviously obtained from the context or the context illustrates otherwise, the same numeral in the drawings refers to the same structure or operation.

It should be understood that the terms “system,” “device,” “unit,” and/or “module” are used herein as a way to distinguish between different components, elements, parts, sections, or assemblies at different levels. However, if other words may achieve the same purpose, the terms may be replaced with alternative expressions.

As indicated in the present disclosure and in the claims, unless the context clearly suggests an exception, the words “one,” “a,” “a kind of,” and/or “the” do not refer specifically to the singular but may also include the plural. In general, the terms “include” and “comprise” suggest only the inclusion of clearly identified steps and elements, which do not constitute an exclusive list, and the method or device may also include other steps or elements.

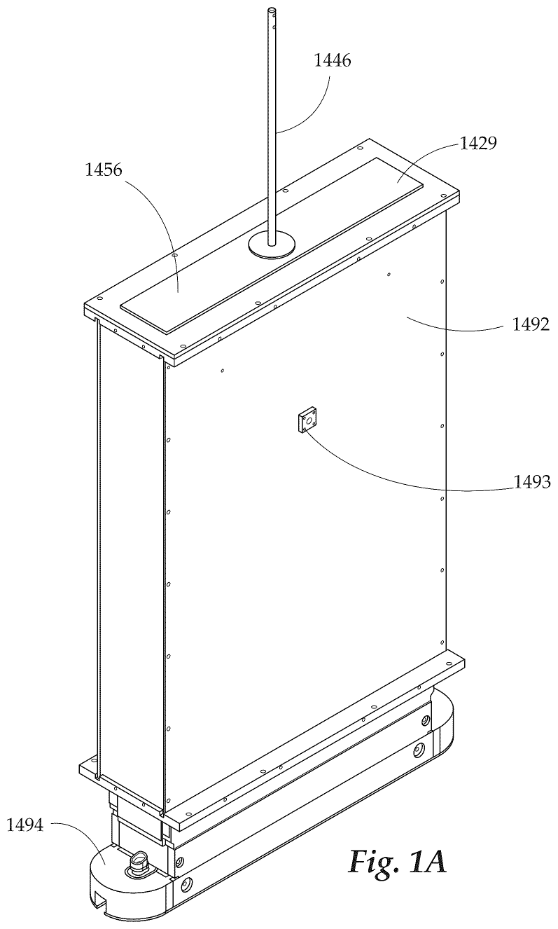

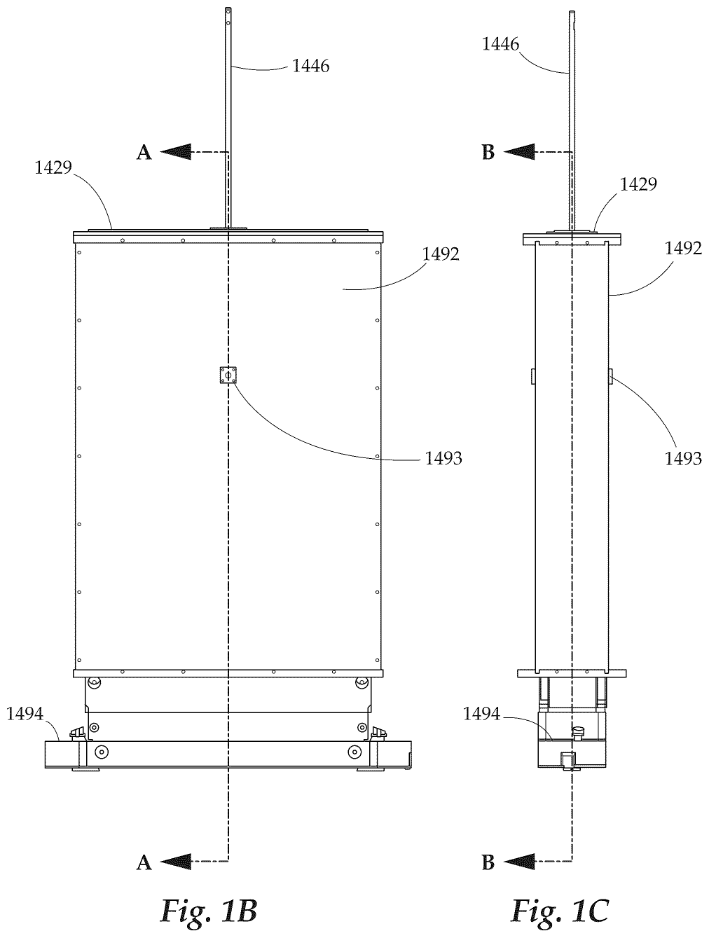

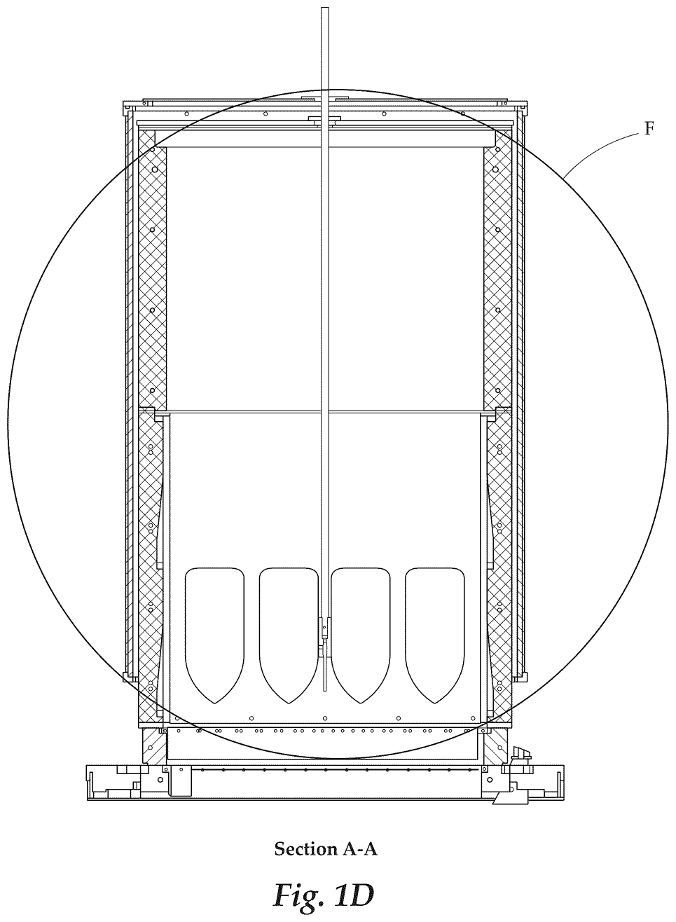

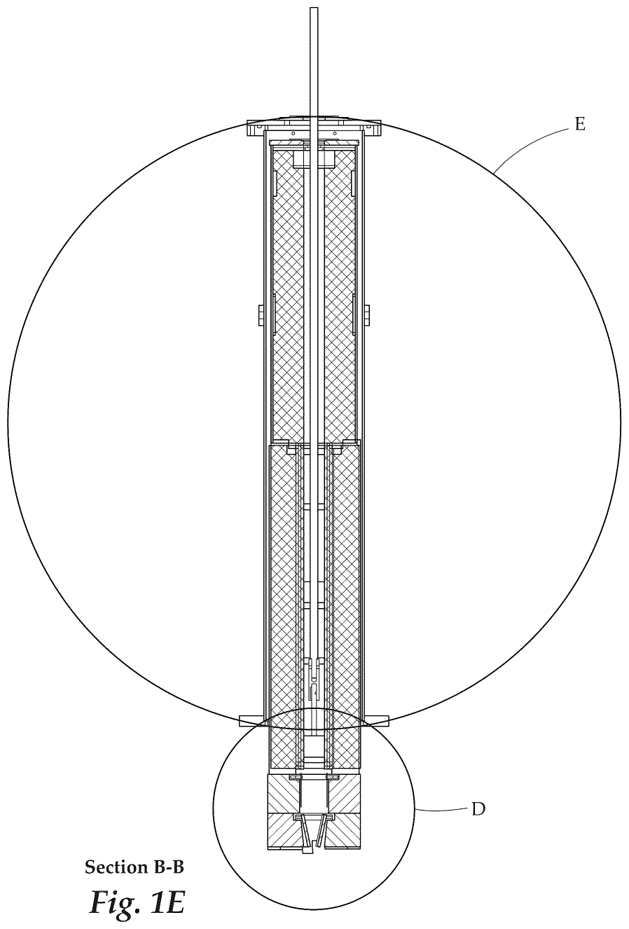

FIG. 1A is an isometric view diagram showing the presently disclosed thermal chimney, according to some embodiments of the present disclosure. FIGS. 1B and 1C respectively shows the front view and side view thereof.

In some embodiments, the presently disclosed thermal chimney may include an insulation, which may comprise rectangular blocks of rigid graphite felt. These blocks may be separated by gaskets of soft graphite felt, to control gas flow. In some embodiments, the insulation may be housed in an aluminum chimney 1492, which may protect it from the atmosphere. In some embodiments, alternatively, the aluminum chimney 1492 may be made of other materials with good heat resistance and corrosion resistance, such as stainless steel, titanium, carbon fiber composite, etc. In some embodiments, the dimensions of the presently disclosed thermal chimney may suit the dimensions of the crystal an operator plans to grow. For example, if a crystal plate is to be grown, the thermal chimney may be shaped as a rectangular cuboid with a much larger height and length compared to its width to fit a plate inside. This configuration may allow for A-plane growth of the seed 1438.

In some embodiments, a bottom part of the thermal chimney may have three levels, which may function to fit the bars and plates to be discussed in detail in the later sections. In some embodiments, a bottom level may be in the shape of an elongated rectangle, and two window holders 1494 may be placed at each end of the elongated rectangle. The window holders 1494 may contain sapphire windows, allowing for visual access to a die or crucible placed at the bottom part of the thermal chimney. In some embodiments, argon may flow both inside and outside of the thermal chimney. Here, argon is chosen as an inert gas with a relatively low price. In some embodiments, there may be a small gap between the sapphire windows and the window holders 1494 to allow a small amount of argon exchange between the inside of the sapphire windows and the outside of the sapphire windows.

In some embodiments, a positioner 1493 may be placed at the middle of a front side of the thermal chimney. In some embodiments, the positioner 1493 may be a graphite rod piercing through a front surface of the aluminum chimney 1492. The positioner 1493 may push the insulation to hold the insulation in place. As there may be a small gap between the crystal and the insulation, the insulation may tilt easily during crystal growth. In some embodiments, more than one positioners, positioners placed at different locations, or positioners of different types may be used. The positioners may be adjusted manually or automatically.

In some embodiments, a top surface of the thermal chimney may be sealed by a lid 1622 with a quartz window 1456. In some embodiments, a seed shaft 1446 may stick out of a top surface of the thermal chimney in the middle. In some embodiments, the seed shaft 1446 may be sealed by a lower shaft seal 1455 and upper shaft seal 1429. These parts and components have been discussed in the summary section and are going to be discussed in greater detail in the later sections.

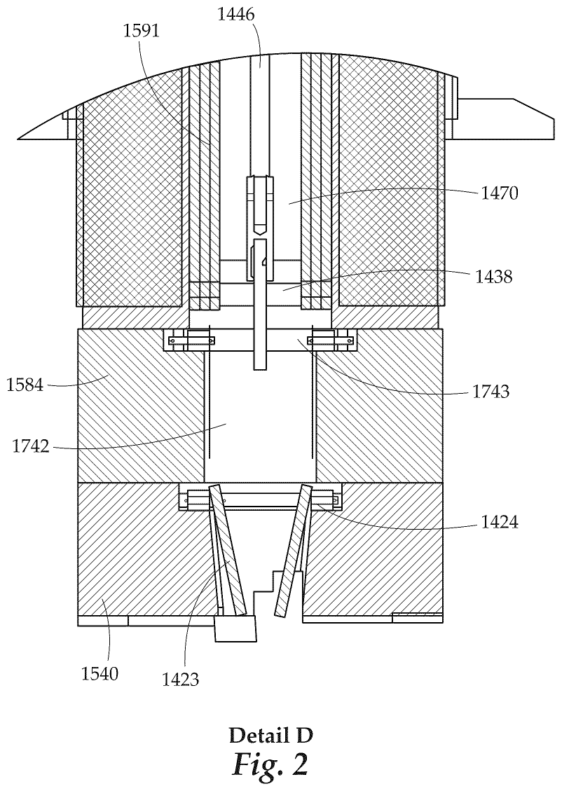

FIG. 1D is a cross-sectional view of the presently disclosed thermal chimney, in the front view direction; and FIG. 1E is a cross-sectional view thereof, in the side view direction. In FIGS. 1D and 1E, three cross-sectional areas D, E, and F are defined, whose detailed views are illustrated in FIGS. 2-4.

FIG. 2 is a detailed view of the cross-sectional area D, which is a lower part of the presently disclosed thermal chimney, in the side view direction, according to some embodiments of the present disclosure. FIG. 2 shows the two bottom levels of the presently disclosed thermal chimney, and a part of the third level.

As discussed above, the bottom part of the thermal chimney may contain three levels, and the three levels, like the rest of the thermal chimney, may be made of rectangular blocks of rigid graphite felt. The graphite felt may serve as insulation.

As shown in FIG. 2, in some embodiments, a lowest level of rigid graphite felt 1540 may be lined with tungsten plates 1423. In some embodiments, each of the tungsten plates 1423 may be about an inch wide and may hang freely from a first graphite bar 1424. Only the top of the tungsten plates 1423 may be fixed to the first graphite bar 1424; the bottom parts of the tungsten plates are not fixed to the insulation 1540. In some embodiments, the first graphite bar 1424 may be placed at the top of the lowest level of rigid graphite felt 1540. The bottoms of the plates may be approximately level with the bottom of the growing crystal. Tungsten may protect the felt insulation from sapphire and tungsten vapors, so that the sapphire will not react with the insulation 1540. The material tungsten is chosen here for having an exceptional heat tolerance, as the temperature at this level may be as high as approximately 1,950° C. Also, here, a plurality of small plates, rather than a long plate, is chosen for protecting the insulation 1540. This is because a long plate may warp due to differential thermal expansion, as its bottom is hotter (so expands more) than its top.

In some embodiments, the next level of insulation 1584 may be lined with graphite plates 1742, also hanging freely from a second graphite bar 1743. These plates may be larger, at about 4″ wide in some embodiments. Like the tungsten plates 1423, the graphite plates 1743 may protect the insulation from being contaminated or reacting with the sapphire. Since the temperature is still ˜1,850° C. at this level, graphite is chosen because of its excellent heat tolerance (although may not be as good as tungsten), and graphite is also more cost-effective than tungsten. Moreover, tungsten is a good conductor of heat, and graphite is a poor conductor of heat. The heat transfer upward may be slowed down because of the lower rate of heat transfer of graphite. Hence, the choice of using tungsten plates at the bottom level and graphite plates at the second level ensures that the heat is conducted up the thermal chimney at a slower rate, and as discussed in the background section, a steeper thermal gradient may be maintained. Also, given that the temperature of the second level is lower than that of the bottom level, the graphite plates 1743 can be longer than the tungsten plates 1423 to prevent warping.

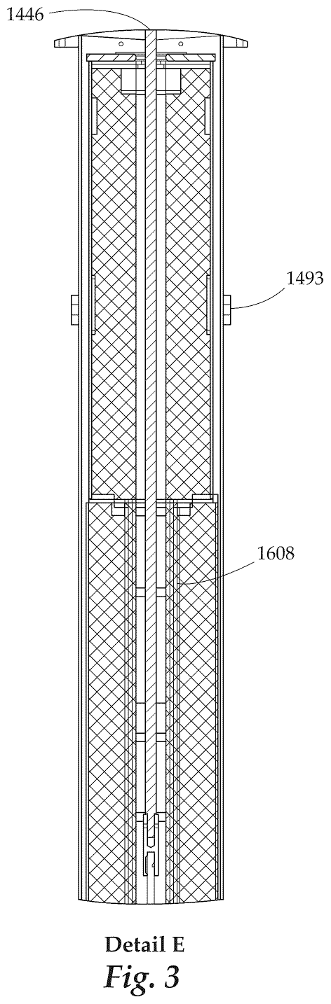

FIG. 3 is a detailed view of the cross-sectional area E, which is a lower part of the presently disclosed thermal chimney, in the side view direction, according to some embodiments of the present disclosure. FIG. 3 shows a top level, and a part of the third level of the thermal chimney.

In some embodiments, the third level may be lined with three layers of soft graphite felt 1591. The temperature at this level may be or approximately be the precipitation temperature of the carbide and oxide vapors, at which they condense into solid particles, which form ferns. The soft graphite felt may adsorb these impurities, inhibiting the formation of ferns. This configuration may provide a substantial reduction and, in many cases, elimination of the formation of ferns, which solves a common problem in the art.

In some embodiments, the topmost level of the insulation may not be lined.

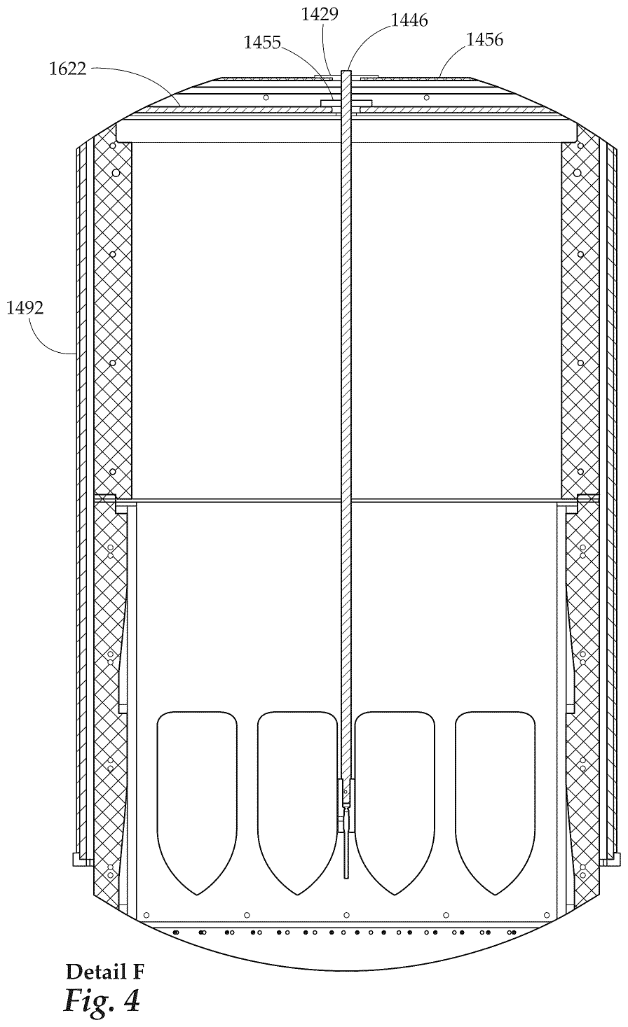

FIG. 4 is a detailed view of the cross-sectional area F, which is a top part of the presently disclosed thermal chimney, in the front view direction, according to some embodiments of the present disclosure. FIG. 4 shows the topmost level of the insulation and the lid.

In many embodiments, the presently disclosed thermal chimney may be capped with a transparent quartz cover 1622, which may seal to both the felt chimney (on its bottom) and the aluminum enclosure (on its edges) 1592. It may have a hole in the middle to allow passage of a seed shaft 1446 and seed holder 1470 (attached to the end of the seed shaft). A seed 1438 may attach to the seed holder 1470. The gap between the top of the cover 1662 and the seed shaft 1446 may be sealed by a thin floating quartz disk 1455, which serves as a one-way seal, preventing air from entering the chimney. Argon may flow up the chimney during operation, which may cause the disk to float.

Similarly, in some embodiments, the aluminum chimney may be capped with a clear quartz window 1456, with an opening to allow the seed shaft 1446 and seed holder 1470 to pass through. Similarly, the gap between the seed shaft 1446 and the surface of the window may be covered by a floating graphite disk 1429, which may serve as a one-way seal to prevent air from entering the chimney. Again, the disk 1429 may float because of the argon flowing up the chimney.

In some embodiments, the two levels of floating seals may be used to prevent air ingress, as thermal circulation within the chimney may create negative pressure for brief periods. A single floating seal could potentially allow air to be sucked in.

The seed and seed shaft have been described in U.S. Pat. Nos. 11,713,519 and 11,713,520, which are hereby incorporated herein by reference.

As discussed in the summary section, the transparent quartz cover 1622 and clear quartz window 1456 may allow visual access to the inside of the thermal chimney. The flow of argon through the thin floating quartz disk 1455 and floating graphite disk 1429 may prevent the transparent quartz cover 1622 and clear quartz window 1456 from being clouded.

Furthermore, unless explicitly stated in the claims, the use of order, numbers, letters, or other names for processing elements and sequences are not intended to limit the order of the processes and methods of the present disclosure. While various examples have been discussed in the disclosure as currently considered useful embodiments of the invention, it should be understood that such details are provided for illustrative purposes only. The appended claims are not limited to the disclosed embodiments, and instead, the claims are intended to cover all modifications and equivalent combinations within the scope and essence of the embodiments disclosed in the present disclosure. For example, although the described system components may be implemented through a hardware device, they may also be realized solely through a software solution, such as installing the described system on an existing processing or mobile device.

Similarly, it should be noted that, for the sake of simplifying the presentation of embodiments disclosed in the present disclosure and aiding in understanding one or more embodiments of the present disclosure, various features have been sometimes combined into a single embodiment, drawing, or description. However, this manner of disclosure does not imply that the features required by the claims are more than the features mentioned in the claims. In fact, the features of the embodiments are less than all the features of the single embodiment disclosed in the foregoing disclosure.

In some embodiments, numeric values describing the composition and quantity of attributes are used in the description. It should be understood that such numeric values used for describing embodiments may be modified with qualifying terms such as “about,” “approximately” or “generally”. Unless otherwise stated, “about,” “approximately” or “generally” indicates that a variation of ±20% is permitted in the described numbers. Accordingly, in some embodiments, the numerical parameters used in the disclosure and claims are approximations, which can change depending on the desired characteristics of the individual embodiment. In some embodiments, the numerical parameters should take into account a specified number of valid digits and employ a general manner of bit retention. Although the numerical ranges and parameters used in some embodiments of the present disclosure to confirm the breadth of the range are approximations, in specific embodiments, such numerical values are set as precisely as practicable.

With respect to each of the patents, patent applications, publications of patent applications, and other material, such as articles, books, specifications, publications, documents and the like, cited in the present disclosure, the entire contents thereof are hereby incorporated herein by reference. Application history documents that are inconsistent with the contents of the present disclosure or that create conflicts are excluded, as are documents (currently or hereafter appended to the present disclosure) that limit the broadest scope of the claims of the present disclosure. It should be noted that in the event of any inconsistency or conflict between the descriptions, definitions, and/or use of terminology in the materials appended to the present disclosure and the contents described herein, the descriptions, definitions, and/or use of terminology in the present disclosure shall prevail.

In closing, it should be understood that the embodiments described in the present disclosure are used only to illustrate the principles of the embodiments of the present disclosure. Other deformations may also fall within the scope of the present disclosure. Therefore, by way of example and not limitation, alternative configurations of the embodiments disclosed in the present disclosure may be considered consistent with the teachings of the present disclosure. Accordingly, the embodiments described in the present disclosure are not limited to the explicitly introduced and described embodiments in the present disclosure.

What is claimed is:

1. A thermal chimney, comprising:
an insulation providing a space for crystal growth;
an enclosure housing the insulation;
wherein the insulation further includes:
a bottom level lined with tungsten plates, hanging from a first bar;
a second level lined with graphite plates, hanging from a second bar;
a third level lined with soft graphite felt;
a seed shaft and a seed holder housed in the insulation;
two layers of lids placed at the top of the insulation and the enclosure;
two layers of seals respectively placed in a middle of the two layers of lids, secured to the seed shaft.

2. The thermal chimney of claim 1, wherein the insulation is made of rigid graphite felt.

3. The thermal chimney of claim 1, wherein the enclosure is made of aluminum.

4. The thermal chimney of claim 3, wherein the blocks are separated by gaskets of soft graphite felt to control gas flow.

5. The thermal chimney of claim 1, wherein the bottom layer includes one or more window holders, with sapphire windows attached to each of the one or more window holders.

6. The thermal chimney of claim 5, wherein two window holders are respectively placed on two ends of the bottom layer.

7. The thermal chimney of claim 1, wherein a thermal gradient develops along a height of the insulation.

8. The thermal chimney of claim 1, wherein argon flows inside and outside the enclosure and the insulation.

9. The thermal chimney of claim 8, wherein the two layers of seals allow the argon to flow out of the insulation but prevent air from entering the insulation.

10. The thermal chimney of claim 1, wherein the third level is lined with three layers of soft graphite felt.

11. The thermal chimney of claim 1, wherein parts or all of the two layers of lids are transparent.

12. The thermal chimney of claim 1, wherein parts or all of the two layers of lids are made of quartz.

13. The thermal chimney of claim 1, wherein the insulation houses a die at its bottom.

14. The thermal chimney of claim 1, wherein the insulation further includes a topmost level that is not lined.

15. The thermal chimney of claim 1, for growing sapphire crystals.

16. The thermal chimney of claim 1, including a positioner located on a front face of the enclosure.

17. The thermal chimney of claim 16, wherein the positioner is a rod piercing through the front face of the enclosure, wherein the graphite rod is able to apply a force to the insulation to adjust the insulation's position.

18. The thermal chimney of claim 1, wherein the graphite plates are wider than the tungsten plates.

19. The thermal chimney of claim 1, wherein the first bar and the second bar are made of graphite.

20. The thermal chimney of claim 1, wherein a seed is attached to the seed holder.
